(19) United States
(12) Patent Application Publication
(10) Pub. No.: US 2012/0066154 A1
(43) Pub. Date: Mar. 15, 2012

(54) WIND-POWERED TRANSPORTATION AND ELECTRIC POWER GENERATION SYSTEM

(75) Inventor: Richard H. Harrington, Dexter, MI (US)

(73) Assignee: Harrington Electronics LLC

(21) Appl. No.: 12/881,575

(22) Filed: Sep. 14, 2010

(51) Int. Cl. G01R 11/00; G01R 21/00; F03D 5/04; B61C 3/00; B61B 7/06; B61D 15/00

(52) U.S. Cl. 705/412; 104/24; 104/23.1; 105/49; 702/61

(57) ABSTRACT

A wind-powered system and method provides for simultaneous electrical generation and transportation of persons or cargo. A set of cables are strung between a plurality of rigid, upright supports, and a transportation vessel including one or more sails rides along the cables through wind power. The vessel is coupled to the cables through one or more motor-generator units, each motor-generator units being operative to generate electricity as the vessel is pushed by the wind or power the vessel in the absence of wind.

### FIELD OF THE INVENTION

This invention relates to both transportation and electrical energy generation and, in particular, to a wind-powered electrical generation and transportation system.

### BACKGROUND OF THE INVENTION

The use of wind power for transportation dates back thousands of years, and many patents have issued on wind transportation devices. As one example of many, U.S. Pat. No. 23,277, entitled SAIL WAGON issued in 1859. The invention improves upon existing designs by lowering the center of gravity, thereby increasing the stability of the sail cloth. Numerous other sailboats and wind-powered vehicles, including bikes have also been devised.

More recently, the need for alternative energy sources has been revitalized due to rising energy costs. The use of wind power to harness energy is also not new. In addition to windmills and modern turbines that use blades, systems with multiple sails have also been used to generate electricity.

U.S. Pat. No. 5,758,911 describes a linear motion wind driven power plant based upon a closed-loop track having a plurality of carriages configured to move thereabout. At least one sail is formed to each of the carriages so as to be rotatable 360 degrees of azimuth. At least one electrical power generator generates electrical power from the movement of the carriages around the track. A sail assembly is defined by the sail, a sensor system for sensing lift generated by the action of the wind upon the sail, and a controller which causes the sail to turn to a position wherein the sensed lift of the sail is approximately maximized.

A wind power plant for producing electrical energy on a large scale is disclosed in U.S. Pat. No. 6,749,393. The system comprises a base and a housing rotatable on the base around a vertical axis. A “wind tail” attached to the housing rotates the housing toward direction of the wind, utilizing the power of the wind, and produces additional tunnel suction to the flow of the wind from front side to back side of the housing. A plurality of turbines, equipped with rotors with wide blades, is mounted inside the housing one above another. Deflectors cover from the wind the front side of the rotors above their axis of rotation while computer controlled governors are covering the remaining front side of the rotors below their axis of rotation, keeping steady the speed of rotation of the rotors.

Despite advances such as those just described, no known system has been proposed which efficiently and effectively provides both transportation and electrical power generation in the same configuration to carry people and/or cargo.

### SUMMARY OF THE INVENTION

This invention resides in a wind-powered system and method that provides for simultaneous electrical generation and transportation of persons and cargo. In the preferred embodiment, a set of cables are strung between a plurality of rigid, upright supports, and a transportation vessel including one or more sails rides along the cables through wind power. The vessel is coupled to the cables through one or more motor-generator units, each motor-generator units being operative to generate electricity as the vessel is pushed by the wind or power the vessel in the absence of wind.

While a single transportation vessel or “cable sailor (CS) is claimed, multiple vessels are envisioned. The rigid, upright supports may be towers or buildings, including horizontal cross beams enabling different vessels to travel in different directions. At least one cable is connected to earth ground to protect each vessel and its occupants from lightening.

Each vessel may include a wing-shaped body to provide lift, including a computer-controlled tail section comprising of an elevator, horizontal, vertical stabilizer, or combinations thereof. Each vessel may include a body with a rudder to help reduce cable loading and increase speed and efficiency.

At least one of the cables also carries electricity to or from the vessel. The electrical power-carrying cable may be one of the car-supporting cables, and the electrical conductor coupling the electrical energy generator to the electrical power-carrying cable may include a pulley, a wiper, or other commutator. The motor/generator unit may include an electrically conductive idle pulley in contact with a cable carrying electricity. The motor/generator unit may include one or more brush assemblies providing electrical connection to a cable carrying electricity.

An electrical storage device may be provided on a vessel to store electrical energy required for use or generated during use. The overall system may further include a source of electrical power, and wherein the electrical power-carrying cable carries electrical energy from the source to power the vessel from support to support in the absence of wind. The motor/generator unit associated with a vessel may use regenerative braking to either charge an on-board battery, or provide current to a power grid. A cable disengage/tension mechanism may be provided, enabling a vessel to be placed on, or removed from, a cable. A vessel may further include an over-tension break-away module to disengage from a cable.

A computer controlled system may enable a vessel to maintain a constant altitude compensating for the parabolic cable droop that occurs because of gravity. A dual-tapered main cable holder may permit the Motor/Generator unit to pass by a tower or any cable support device with reduced vibration.

The rigid, upright towers may be placed in a rectangular array, facilitating vessel tacking. The towers may also be placed in an array or X pattern facilitating overtaking and passing of vessels. The system may further include an anti-collision device to prevent rear-end or head on collisions. Apparatus may be used to calculate and record the total amount of energy that is either produced or used by the vessel. A data network may be provided, enabling vessel movement to be tracked in relation to support location enabling the vessel to be credited or debited with respect to power generated or used.

Computer-controlled, automatic sail deployment may be provided to maximize power generation, and photovoltaic sail material may be used to generate additional electricity. Multiple Anti-Collision systems are also disclosed along with method aspects of the invention.

### BRIEF DESCRIPTION OF THE DRAWINGS

FIG. 1 a schematic illustration of a system according to the invention including a sailing vessel coupled to cables supported by towers;

FIG. 2 illustrates an alternative embodiment that uses a plurality of support cables that do not ordinarily carry any electrical current, and power cables that run parallel to the support cables, but with a connection to earth ground for lightning protection.

FIG. 3 is a more detailed drawing of a CS “cable sailor” vessel including motor/generator modules;

FIG. 4A is a front-back view of a motor/generator module constructed in accordance with the invention;

FIG. 5 is a drawing of a cable holder according to the invention;

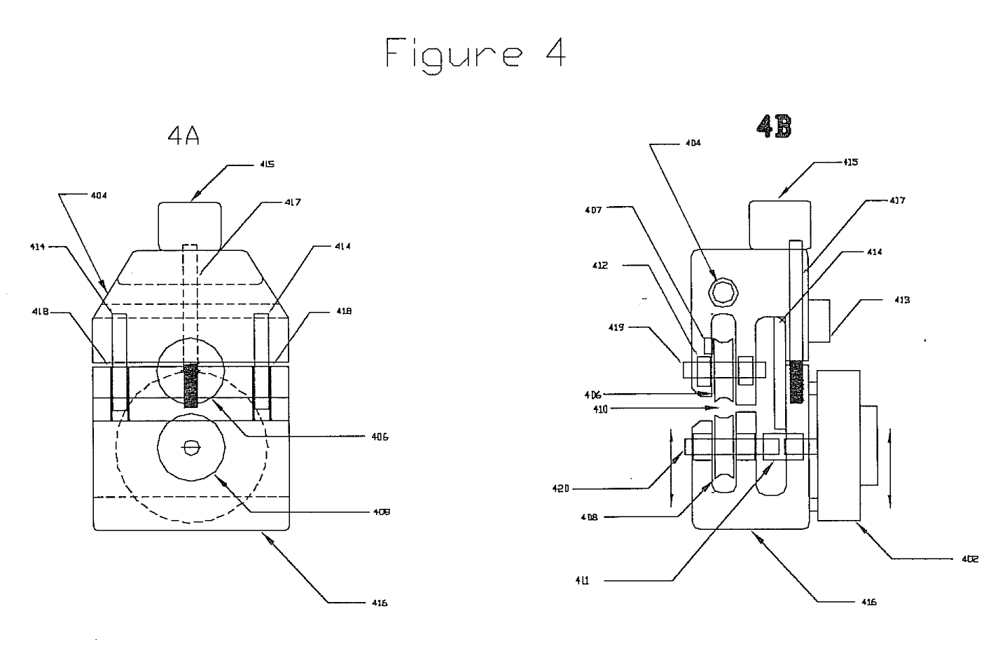

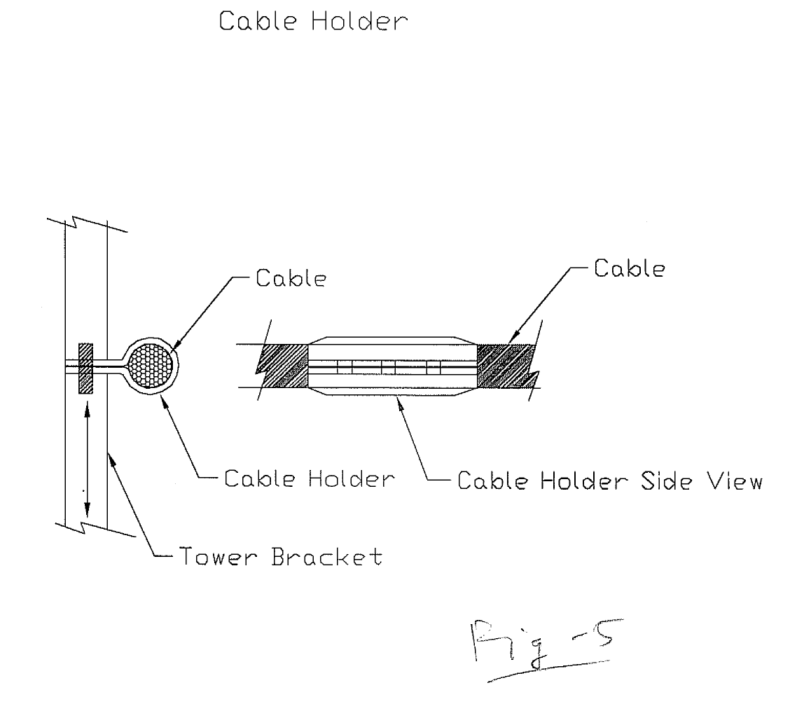

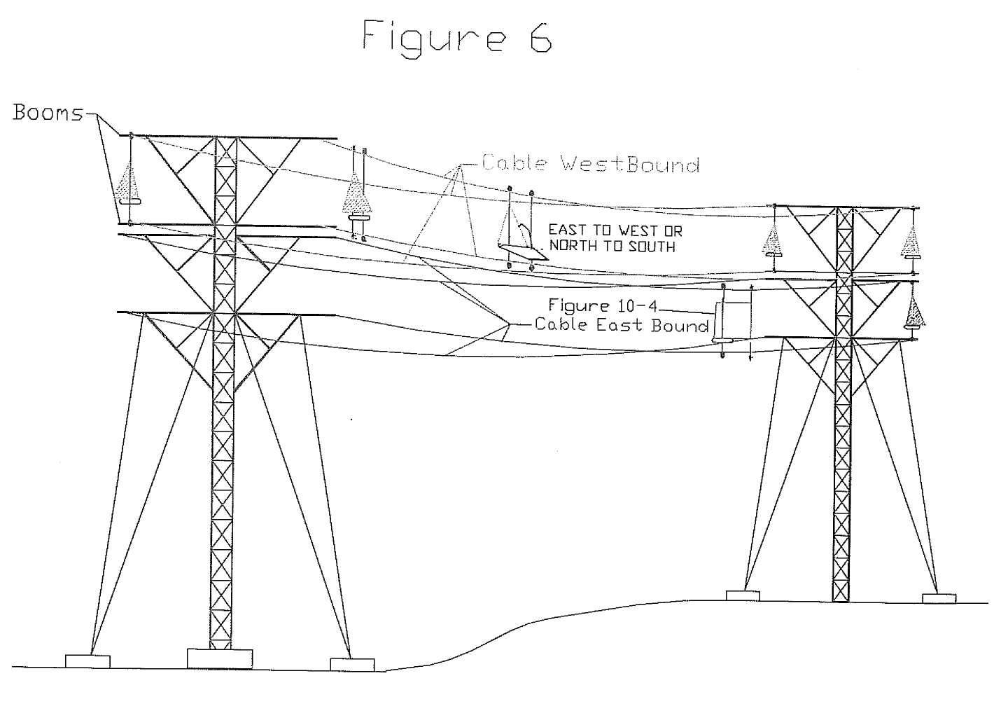

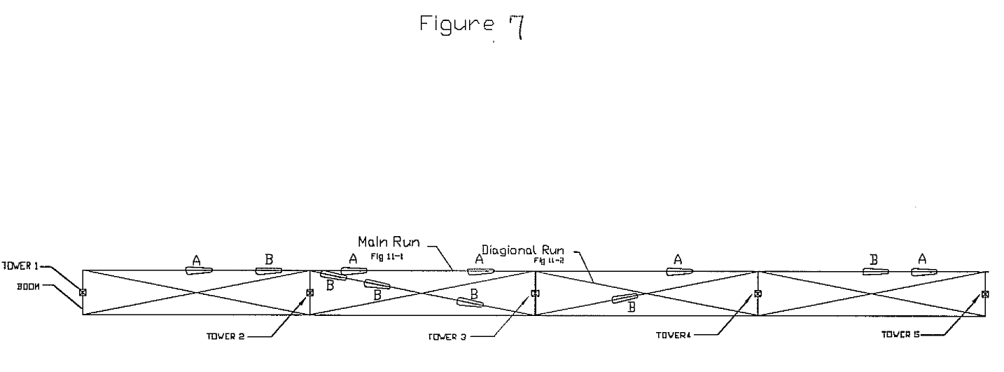

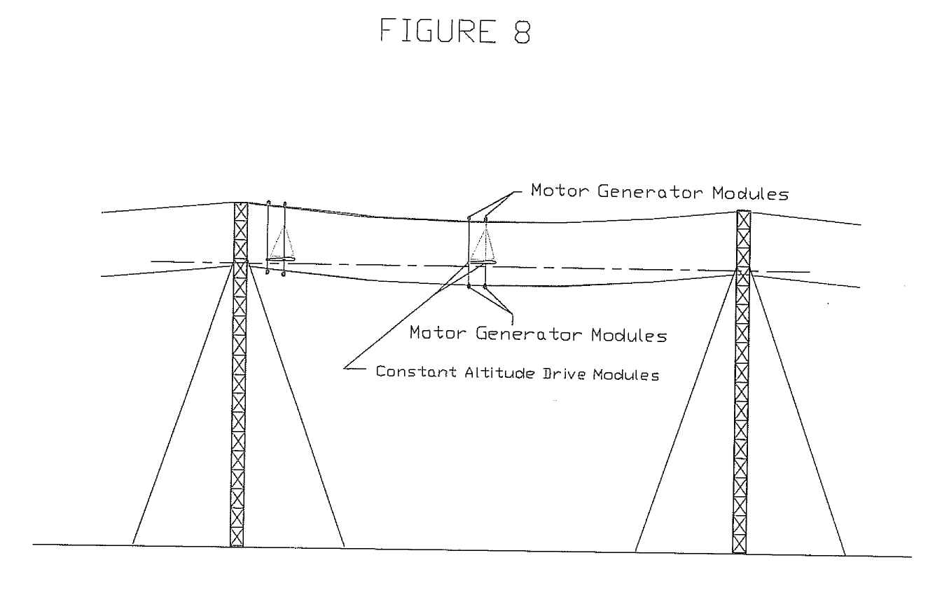

FIG. 4B is a side view of the device of FIG. 4A;

FIG. 6 is a drawing that shows upper/lower and/or side-by-side cable runs enabling travel in different directions;

FIG. 7 is a top-down view illustrating how diagonal switching may be implemented;

FIG. 8 depicts a system for achieving a constant altitude during travel; and

FIG. 9 shows a Cable Sailor with various parts of the vessel called out in detail.

### DETAILED DESCRIPTION OF THE INVENTION

This invention resides in a system that will simultaneously generate electrical power while transporting people and/or goods over various distances in vessels on cables supported by spaced-apart upright towers. The “cable sailor” (CS) vessels are primarily powered by the wind; however, in the event the wind is not strong enough to move the CS vessels from one location to another, they may be powered by the same or a different set of electrical cables, also supported by the towers. Alternatively, the CS vessels may include rechargeable batteries or supercapacitors that drive the vessels in low-wind conditions. The vessels may also transfer excess stored energy to a power grid. To generate additional electricity, the sails may include flexible solar panels. Flexible Solar Sails made from products such as Uni-Solar manufactured by Uni-Solar located in Rochester Hills, Mich. have a Photovoltaic Laminate made from amorphous silicon. The system may further include apparatus that calculates and records the total amount of energy that is either produced or used by the vessel.

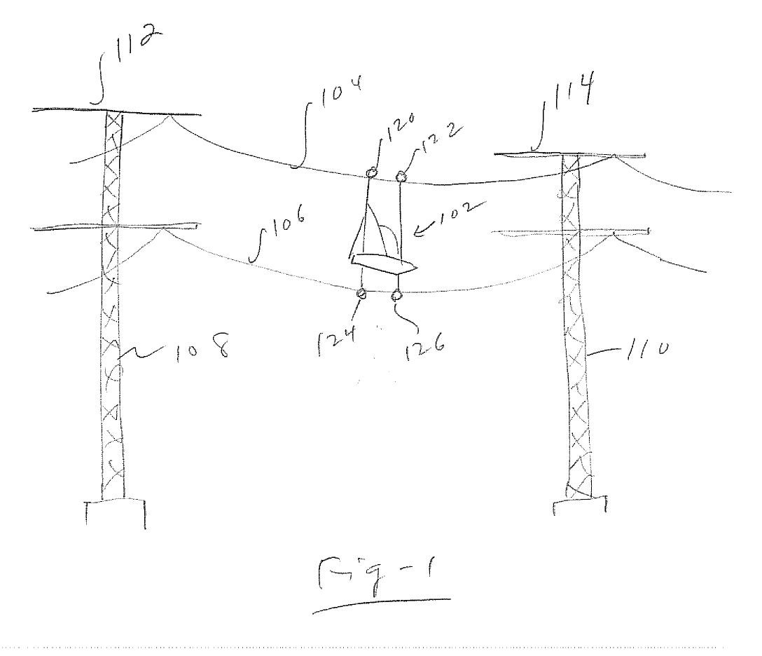

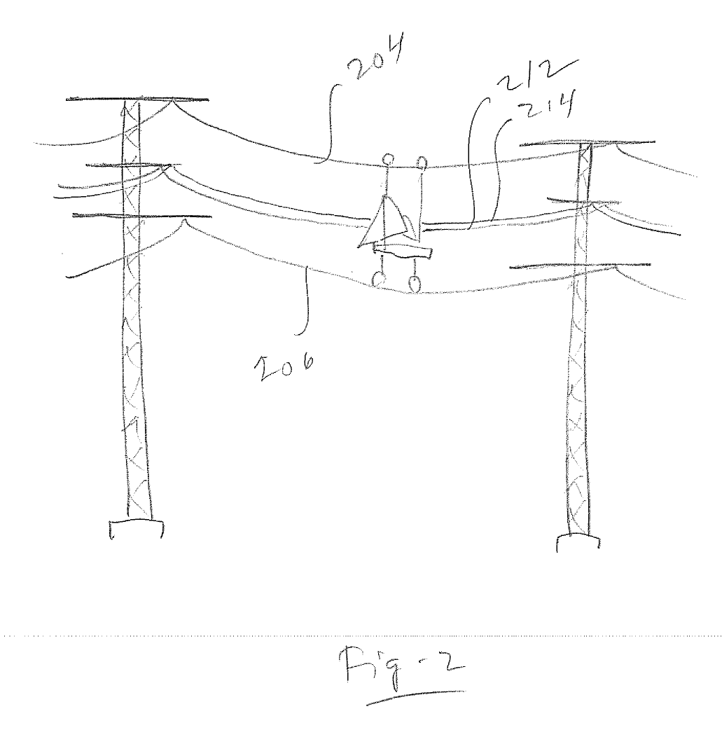

FIG. 1 is a schematic illustration of a system including a sailing vessel 102 coupled to cables 104, 106 supported by towers 108, 110. The towers 108, 110 preferably include horizontal cross beams 112, 114 to support CS vessels moving in the opposite direction as described below. The CS vessel 102 rides on the upper and lower cables 104, 106 using a plurality of motor/generator units 120, 122 and 124, 126, also described herein. In the embodiment of FIG. 1, the cables 104, 106 provide two functions, one is mechanical—to carry the CS vessel—and the other is to conduct electricity.

An alternative approach, depicted in FIG. 2, uses a plurality of support cables 204, 206 that do not carry any electrical current, and power cables 212, 214 that run parallel to the support cables 204, 206. A wiper system extending from the CS car makes contact with the power cables 212, 214 to transfer electricity, thereby allowing for the optimization of both sets of cables.

Whether or not they support the cars, the power cables will be bare wire. Transferring the electricity from each CS to and from the power cables may be done in the conventional approach using a spring wiper that same as ground transportation i.e. electrical trolleys. The preferred approach uses conductive pulleys with a rotating disc attached to the pulley. Brushes contact the rotating disc such as the IDLE Pulley described with reference to FIG. 4, to transfer the electrical current to and from the CS.

The invention preferably uses two Power Grids, one being the main power grid that is already present in most countries, and the second being the CS power grid. The CS Power Grid may be AC or DC, but three-phase AC is the preferred choice as it will be easier to connect to the main power grid through transfer stations.

The cables for the CS vessels will be high enough off the ground to achieve a sizeable advantage in wind speed compared to the wind speed near the ground. The optimal altitude will be determined by cost verses efficiency, however 200 to 250 feet presents a workable range.

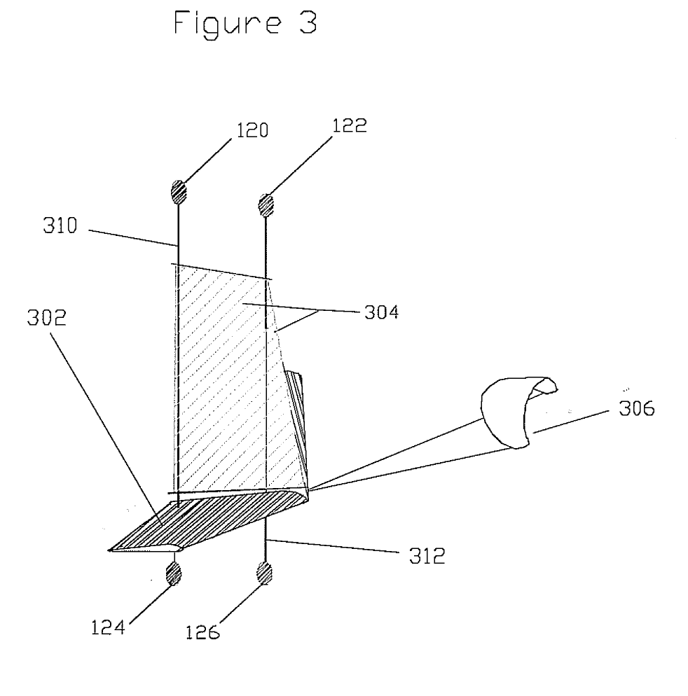

FIG. 3 shows a CS vessel with a combination wing and main body 302 with sails 304, 306, Motor Generator modules 120, 122, 124, 126, and support structures 310 and 312. FIG. 9 is a more detailed drawing of a CS vessel including motor/generator modules 907 and 908. Three or more motor/generator modules would typically be used to both support each car and to either source the cables with electrical power, or to receive electrical power in the case of low wind speed. Two cables would be the minimum number required to conduct electricity, with a third cable (not shown) at earth ground potential for safety reasons in case of a lightning strike. This cable would be connected to a metal shell which would serve as a Faraday Shield around the body 901 of the vehicle. Other parts of the CS vessel are the sails 911, 912 and 910; the Vertical Stabilizer 902, the Rudder 903, the Horizontal Stabilizer 904, Elevator 905, Wing/Body 901.

The body of the CS 901 may form a combination wing and enclosure to carry people and/or cargo. The body will be very aerodynamic with a lifting body shape for the main body. It may also have wings to help it fly through the air unloading the supporting cables to some degree and increasing overall efficiency.

A primary sail 911 would be held by supports 913 and 915 between the upper and lower motor/generator modules. This sail may be square, triangular or a plurality of sails of various types such as a Main, a Jib, spinnaker, etc. A sky sail 910 may also be provided for enhanced stability and/or steering. Square sails would be a natural for the CS as they can have a much larger sail area than triangular ones. Roller Furling sails will be used wherever possible. Roller Furling Flexible Solar Sails can be used if available as they will serve a dual function.

The CS may further include a separate wing and/or elevators and a rudder to improve the stability of the CS as it is carried by the wind. The Wings, Ailerons, Vertical and Horizontal Stabilizer and Rudder and Elevator shown in FIG. 9 will not only add stability, but will also help off-load the cable loading by having the Cable Sailor flying while still attached to the cables. This is easily envisioned as the CS should achieve 4 to 5 times the wind speed do to the sail having lift which transfers into forward velocity.

FIG. 6 illustrates CS Vessels traveling simultaneously in two different directions. The drawing also shows how multiple horizontal beams at different altitudes can accommodate more traffic. Velocities of 100 mph may be achieved in a 25 MPH wind do to the action of the sails being at some desired angle in reference to the wind direction. The CS has an advantage over a common sail boat due to the use of cables instead of a keel to prevent side slipping when the wind is pushing it sideways. The cables will extend laterally some limit and no further, whereas a sail boat will constantly slip sideways. Yet another advantage over a common sailboat is the much reduced friction of the Motor/Generator Modules pulleys compared to hull and keel drag in the water. Air is 25 times less dense than water, so additional advantages are realized here as well.

Tests have indicated that a large area surface is several times more efficient in producing power compared to the same area circumscribed by a turbine blade. It is well known that sail area has a direct and linear relationship to effective horse power with sail boats. The typical turbine blade has an aspect ratio of 10 or 15 to 1 compared to the surface area circumscribed by a turbine blade. That is the turbine blade width is 10 to 15 times smaller than the length of the blade. The problem encountered by increasing the width of the turbine blade is increased air turbulence encountered by the blade entering the disturbed air created by the preceding blade. A sail however large does not have these problems and that's why the linear power versus sail area holds up. The test results comparing a turbine blade with a diameter X and a wind gathering device of the same diameter showed that the large area wind gathering device produced 3.64 more power that the turbine blade. The theoretical value of this increase of power is much more, and look like the sail area versus HP relationship which is know to be directly proportional.

A Motor/Generator Module constructed in accordance with the invention is depicted in FIG. 4. FIG. 4A is a front-back view, while FIG. 4B is a side view of the same device. Each module provides multiple functions. The first function is to attach the Cable Sailor (CS) to the cables to support the weight of the CS and wind forces. The second function is to generate electricity to the local Cable grid which, in turn, supplies the Main Power Grid. Each Motor/Generator Module will be computer-controlled by the CS. The third function of the Motor/Generator Module is to propel the CS along the cables when the wind velocity is too low. An additional function of the Motor/Generator Module is to connect the CS to Earth Ground for safety issues like lightning. This is accomplished by having brushes contacting the Idle Pulley of the Motor/Generator Module attached to the frame and conducting parts of the CS.

The Motor/Generator module may be designed around a MANTA unit, part number PMG226PMG. This device is capable of 10 HP continuous output power, or may function as a 8,000 watt DC Generator. It can generate 19 HP for 2 minutes, and 28 HP for 45 seconds, if needed. It is thermally limited, which is the reason for the different HP ratings. This particular Motor/Generator is very efficient and light (22 LBS) and 90 percent efficient over a wide range of torque. Two or more Motor Generators would typically be used.

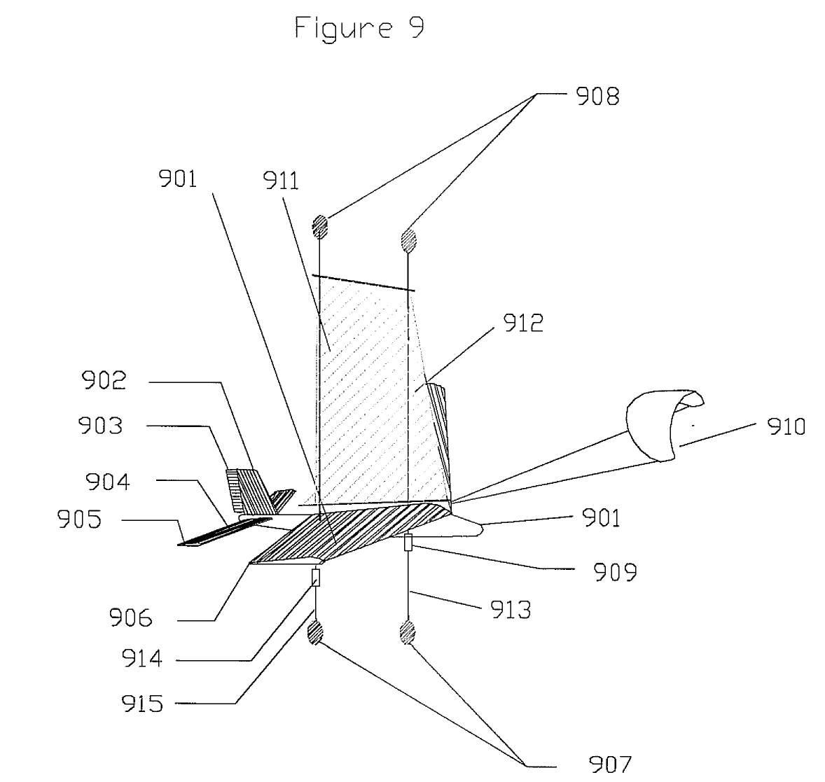

In addition to the Motor/Generator unit 402 in FIG. 4, a second motor 415 is used to vary the tension of an electrically conductive idle pulley 406 relative to an insulated Drive pulley 408. 417 is a drive screw that engages into 416, the bottom cavity. 414 comprises a dovetail assembly. 412 is an insulating bearing for the idler pulley 406 drive shaft 419. 411 is a flexible coupling that connects the Motor Generator 402 to the drive shaft 420. A brush assembly 407 is used to make electrical contact to the conductive idle pulley 406. The motor 415 may also be used to disengage the Motor/Generator Module from the cable disposed in region 410, as necessary. The Disengage/Tension Motor 415 will preferably include a mechanical locking device to help prevent disengaging while moving along the cable. FIG. 5 is a drawing of a cable holder according to the invention. This dual-tapered main cable holder that permits the Motor/Generator unit to pass by a tower or any cable support device with reduced vibration. 502 is the cable holder with the cable 501 passing through it. 503 and 504 represent two elements of the cable tower beam 112 shown in FIG. 1 used to clamp the cable holder 502 in FIG. 5.

### Cable Configurations

One embodiment of the invention uses cables for support and for a connection to earth ground in the case of a lightning strike. One benefit of this configuration is that only two cables are necessary, a top and a bottom cable. The cables are designed primarily for strength without concern for IR drop. The cables must be conductive, but that is the only electrical restraint.

An alternative embodiment uses two cables at some electrical potential, either AC or DC. The cables in this case also act as the mechanical support. The CS vessel will have a battery bank on board that will be charged by the wind powering the CS along the cables. If the wind dies down, the CS can be powered by the batteries, or through powered cables if that mode is used. The Cable Sailor will therefore work with just a body along with the control systems and the Sails. The control system controls the Motor Generator Modules, anti-collision system, and commands to the Cable Switching Stations. It will also work with no sails.

### Batteries Only Mode

The batteries will be charged by the wind via the Motor/Generator Modules or by the Tower at a docking station. This docking station can also be used for discharging the batteries to the main power grid in the event a CS vessel is storing excess power. A computer will be used to ‘credit’ the CS as it is discharging the batteries. This same computer will be used to ‘debit’ the CS in the event it needs to be charged. Regenerative braking will also be employed to further charge the batteries. Braking may be required, for example, if tacking is carried out on a diagonal Run as shown in FIG. 7.

Lightweight batteries such as Li-ion or Li-air are preferably used to reduce inertia and to facilitate rapid charge and discharge. As battery technology progresses, other battery types or fuel cells may be used. Super capacitors may also be used either in place of, or to complement the batteries. Having a very low impedance, supercap3 allow for a sudden change of speed, whether it be accelerating or decelerating.

### Cable Switching Devices

In preferred embodiments, the Cable Sailors will be able to switch from a Main Run Cable to a Diagonal Run or some other cable such as a cable going to a different city or building. FIG. 6 is a drawing that shows upper/lower and/or side-by-side cable runs enabling travel in different directions. FIG. 7 is a top-down view illustrating how diagonal switching may be implemented. This may be accomplished in much the same way as railroad tracks are switched. In the case of the Cable Sailor, the switch points will go from being cables to rigged steel rods.

A typical implementation involves multiple safety subsystems. Over Tension Break-Away Modules 909 and 914 shown in FIG. 9 connect to the lower Motor Generator Modules. When the tension reaches or exceeds a predetermined value, indicating that the Cable Switching Devices are failing to operate properly, they will detach the lower Motor Generator Modules from the cables running to the Cable Sailor. The Cable Sailor will now be attached to the upper cable(s) only and will operate in a “limp Home” mode. The sails will be automatically pulled in. If provided, the ailerons and tail section, which may be composed of a vertical Stabilizer and a Rudder, will help stabilize the Cable Sailor until it can return to a tower with an off-loading capability.

Multiple anti-collision devices and methods will also be employed. Referring to FIG. 6, all traffic going from west to east will be on the lower booms of the tower, and conversely all traffic going from east to west to be on the upper booms of the tower. Sensors will be used to prevent rear-end collisions and overtaking collisions. Dedicated computers will be used to control the Motor Generator Modules to prevent such occurrences. technologies may be used for such purposes. A computer uses inputs from laser, sonar, GPS or DTR (time domain reflectometry) subsystems to make the necessary signal changes to the Motor/Generators and possible the sail or sails as well.

To pass a slower CS may be accomplished by first detecting a slower CS and then directing the slower CS to take different route at a cable switching station. FIG. 7 shows a top view of the several towers with CS labeled “A” overtaking CS labeled “B”. Using this technique, the slower CS typically will not have to slow down, as it must traverse a longer distance the faster CS.

Passing a stopped CS is achieved by first detecting it over the network, and then taking the proper course to avoid it. Collision avoidance is necessary at and near the switch points. This will be computer controlled as well as having Manual Brakes on all CS that can be activated by the on board personal. The computer control system will attempt to avoid close calls so that inadvertent emergency braking is kept to a minimum.

Each tower will include Cable Switching Stations commanded by computers which, for safety reasons, may also be controlled manually if desired. Each switch has two positions, Main Run and Diagonal Run. The Main Run is the straight cable in FIG. 6, and the Diagonal Run is shown in FIG. 7.

### Constant Altitude Travel

The cables attached to the towers will have a parabolic shape due to gravity. This cable droop would cause the CS to be moving up and down as it traverses the cable tower network. At sufficient speeds, this would make for an unpleasant ride for the passengers. As such, embodiments of the invention may include systems and methods for achieving a constant altitude. This is illustrated in FIG. 8. Rather than traverse a parabolic path, sensors such as accelerometers, and very sensitive air pressure sensors connected to a computer that controls a plurality of servos located in the CS to achieve straightened-line travel. The servos are also connected via drive pulleys to cables traversing the span between the upper and lower Motor/Generator Modules.

Elevators and stairs will be provided at selected towers, with some provision of getting up and down at every tower such as a built-in ladder. The elevators can be used for humans and goods to get to and from the CS. Elevated Rest Areas would be provided to save time and power (assuming the elevator is needed). This could be accomplished by having the Rest Area being a tall building replacing the standard towers and having the cable booms extend laterally from the building. Cable Switches would be employed to get the CS into and out of a parking area.

Elevated Restaurants would save time and power (assuming the elevator is needed). This could be accomplished by having the restaurant being a tall building replacing the standard towers and having the cable booms extend laterally from the building. Cable Switches would be employed to get the CS into and out of a parking area.

In terms of applications, large cities with tall buildings would be a good fit for the system, as the cables could be run across streets that are normally difficult to traverse because of traffic. Other routes could go down streets but at a few hundred feet off the ground. Building form natural high wind velocity because of the tunneling effect.

I claim:

1. A wind-powered electrical generation and transportation system, comprising:
a plurality of rigid, upright supports;
a set of cables strung between the supports;
a transportation vessel including one or more sails enabling the vessel to ride along the cables through wind power; and
wherein the vessel being coupled to the cables through one or more motor-generator units, each motor-generator units being operative to generate electricity as the vessel is pushed by the wind or power the vessel in the absence of wind.

2. The wind-powered electrical generation and transportation system of claim 1, wherein the rigid, upright supports are towers or buildings.

3. The wind-powered electrical generation and transportation system of claim 1, wherein:
the rigid, upright supports are towers including horizontal cross beams; and
multiple cables strung between the cross-beams enabling different vessels to travel in different directions.

4. The wind-powered electrical generation and transportation system of claim 1, further including at least one cable connected to earth ground to protect the vessel and its occupants from lightening.

5. The wind-powered electrical generation and transportation system of claim 1, wherein the vessel includes a wing-shaped body to provide lift.

6. The wind-powered electrical generation and transportation system of claim 1, wherein the vessel includes a body with computer-controlled tail section comprising of an elevator, horizontal and vertical stabilizer.

7. The wind-powered electrical generation and transportation system of claim 1, wherein the vessel includes a body with a rudder to help reduce cable loading and increase speed and efficiency.

8. The wind-powered electrical generation and transportation system of claim 1, wherein at least one of the cables also carries electricity to or from the vessel.

9. The wind-powered electrical generation and transportation system of claim 1, wherein:
the electrical power-carrying cable is one of the car-supporting cables; and
the electrical conductor coupling the electrical energy generator to the electrical power-carrying cable includes a pulley.

10. The wind-powered electrical generation and transportation system of claim 1, wherein:
the electrical power-carrying cable is separate from the car-supporting cables; and
the electrical conductor coupling the electrical energy generator to the electrical power-carrying cable is a wiper.

11. The wind-powered electrical generation and transportation system of claim 1, further including an electrical storage device on the car to store at least a portion of the electrical energy.

12. The wind-powered electrical generation and transportation system of claim 1, further including:
a source of electrical power; and
wherein: the electrical power-carrying cable carries electrical energy from the source to power the vessel from support to support in the absence of wind.

13. The wind-powered electrical generation and transportation system of claim 1, wherein the motor/generator unit is operative to use regenerative braking to either charge an on-board battery, or provide current to a power grid.

14. The wind-powered electrical generation and transportation system of claim 1, further including a cable disengage/tension mechanism allowing a vessel to be placed on or removed from a cable.

15. The wind-powered electrical generation and transportation system of claim 1, wherein the motor/generator unit includes an electrically conductive idle pulley in contact with a cable carrying electricity.

16. The wind-powered electrical generation and transportation system of claim 1, wherein the motor/generator unit includes one or more brush assemblies providing electrical connection to a cable carrying electricity.

17. The wind-powered electrical generation and transportation system of claim 1, wherein the vessel includes an over-tension Break-away module to disengage from a cable.

18. The wind-powered electrical generation and transportation system of claim 1, further including a computer controlled system enabling a vessel to maintain a constant altitude compensating for the parabolic cable droop that occurs because of gravity.

19. The wind-powered electrical generation and transportation system of claim 1, further including a dual-tapered main cable holder that permits the Motor/Generator unit to pass by a tower or any cable support device with reduced vibration.

20. The wind-powered electrical generation and transportation system of claim 1, wherein the rigid, upright towers are placed in a rectangular array such that tacking of the vessel may occur.

21. The wind-powered electrical generation and transportation system of claim 1, wherein the rigid, upright towers are placed in an array facilitating overtaking and passing of vessels.

22. The wind-powered electrical generation and transportation system of claim 1, wherein the cables are placed in an X pattern when viewed from above facilitating overtaking and passing of vessels.

23. The wind-powered electrical generation and transportation system of claim 1, further including an anti-collision device to prevent rear-end or head on collisions.

24. The wind-powered electrical generation and transportation system of claim 1, further including apparatus that calculates and records the total amount of energy that is either produced or used by the vessel.

25. The wind-powered electrical generation and transportation system of claim 1, further including a data network enabling vessel movement to be tracked in relation to support location enabling the vessel to be credited or debited with respect to power generated or used.

26. The wind-powered electrical generation and transportation system of claim 1, further including a computer-controlled automatic sail deployment to maximize power generation.

27. The wind-powered electrical generation and transportation system of claim 1, further including photovoltaic sail material to generate additional electricity.

28. The wind-powered electrical generation and transportation system of claim 1, further comprising multiple Anti-Collision systems incorporating one or more of the following:
a plurality of cables, each associated with travel in a different direction, and
multiple sensors used to control the Motor Generator Modules.
